(19) United States
(12) Patent Application Publication
(10) Pub. No.: US 2012/0026693 A1
(43) Pub. Date: Feb. 2, 2012

(54) Cooling Apparatus

(76) Inventor: Hiroaki Komaki, Tachikawa-shi (JP)

(21) Appl. No.: 13/149,445

(22) Filed: May 31, 2011

(30) Foreign Application Priority Data
Jul. 28, 2010 (JP) 2010-169639

(51) Int. Cl. H05K 7/20

(52) U.S. Cl. 361/717

(57) ABSTRACT

According to one embodiment, a cooling apparatus includes: a cooling fin which cools heat-generating components by radiating heat of the heat-generating components; a first semiconductor module which serves as one of the heat-generating components; a second semiconductor module which serves as another one of the heat-generating components; a first heat sink which cools the first semiconductor module; a second heat sink which cools the second semiconductor module; a first heat pipe which thermally couples the cooling fin to the first heat sink; and a second heat pipe which thermally couples the first heat sink to the second heat sink. A functional upper limit of a junction temperature of the first semiconductor module is lower than a functional upper limit of a junction temperature of the second semiconductor module, and a heat generation of the first semiconductor module is larger than a heat generation of the second semiconductor module.

### CROSS REFERENCE TO RELATED APPLICATION(S)

The application is based upon and claims the benefit of priority from Japanese Patent Application No. 2010-169639 filed on Jul. 28, 2010; the entire content of which are incorporated herein by reference.

### FIELD

The present invention relates to a cooling apparatus for cooling semiconductor modules.

### BACKGROUND

A high-speed (serial) channel is used as means for improving communication speed between devices. For example, a channel having eight-bit links with a data transmission rate of 5 Gbps at both TX and RX is used.

In the high-speed channel, a temperature fluctuation range is stipulated as a condition for guaranteeing the AC characteristics between TX and RX. However, if the stipulated range is lower than an operation temperature range of a device in a trade-off with its performance, it is necessary to control the temperature of the device.

When temperature control for a micro processing unit (MPU) and a south bridge chip (SBC) is taken as an example, since the MPU has a high operation frequency, a large die area and a large self-leakage current, its power consumption is high at the time of power-on operation and in its standby state due to clock mesh activity. Hence, the temperature of the die of the MPU can be raised by self power consumption before calibration is carried out. On the other hand, since the SBC has a low operation frequency, a small die area and a small self-leakage current, the temperature of the die of the SBC is not raised sufficiently at the time when calibration is carried out.

Furthermore, the high-speed channel has a characteristic in which eye pattern drifts occur due to temperature change. If the temperature fluctuations at both ends of the channel are shifted in the opposite directions, the drifts of the two devices are eventually synergized.

Wiring crosstalk and operation voltage are taken as parameters, other than temperature, significantly affecting an operation margin of the high-speed channel. However, if the temperature environment is not optimized, it is necessary to take countermeasures in which wiring space is made wider to reduce crosstalk (cost increases due to increase in the area of a circuit board), a power supply circuit and components being high in grade are used to stabilize the operation voltage, and the power supply lines on the circuit board are made thicker (the area of the circuit board is made larger, and Decoupling-C and the number of components increases, whereby the cost of hardware increases).

Accordingly, the channel circuit provided in a semiconductor module is ingeniously contrived to perform communication normally even if the temperature of the semiconductor module fluctuates.

Furthermore, there are demands for reducing the temperature fluctuation range in the high-speed channel and for guiding the temperature fluctuations at both ends of the high-speed channel in the same direction. However, means for satisfying these demands are not yet known.

### BRIEF DESCRIPTION OF THE DRAWINGS

FIG. 1 is a block diagram showing an example of a system configuration of an information-processing apparatus according to the embodiment.

FIG. 2 is a flowchart showing an initialization processing flow according to the embodiment.

FIG. 3 is a view showing a configuration example of a cooling apparatus according to the embodiment.

FIG. 4 is a diagram of a thermal radiation equivalent circuit using concentrated constants according to the embodiment.

### DETAILED DESCRIPTION

In general, according to one exemplary embodiment, a cooling apparatus includes: a cooling fin which cools heat-generating components by radiating heat of the heat-generating components; a first semiconductor module which serves as one of the heat-generating components; a second semiconductor module which serves as another one of the heat-generating components; a first heat sink which cools the first semiconductor module; a second heat sink which cools the second semiconductor module; a first heat pipe which thermally couples the cooling fin to the first heat sink; and a second heat pipe which thermally couples the first heat sink to the second heat sink. A functional upper limit of a junction temperature of the first semiconductor module is lower than a functional upper limit of a junction temperature of the second semiconductor module, and a heat generation of the first semiconductor module is larger than a heat generation of the second semiconductor module.

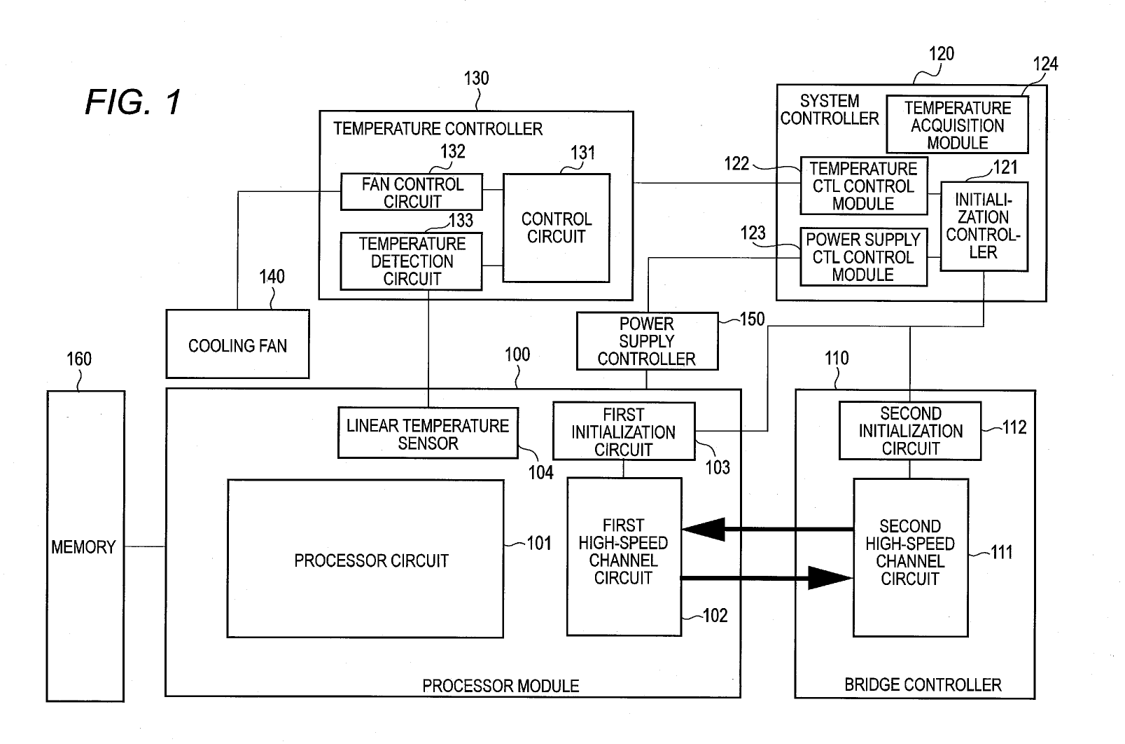

An embodiment according to the present invention will be described below referring to FIGS. 1 to 4.

FIG. 1 is a block diagram showing an example of a system configuration of an information processing apparatus according to the embodiment.

As shown in FIG. 1, the information processing apparatus is equipped with a processor module 100 serving as a first semiconductor module, a bridge controller 110 serving as a second semiconductor module, a system controller 120, a temperature controller 130, a cooling fan 140, a power supply controller 150, a main memory 160, etc.

The processor module 100 includes a processor circuit 101, a first high-speed channel circuit 102 serving as a first high-speed channel circuit, a first initialization circuit 103, and a linear temperature sensor 104. The operation guarantee temperature of the processor module 100 is in the range of 5 to 85° C. Furthermore, the temperature range in which the high-speed channel circuit operates is 5 to 85° C. However, a temperature fluctuation range in which the AC characteristics of the I/O section of the first high-speed channel circuit 102 are guaranteed is ΔT_c=55° C.

The processor circuit 101 is a processor provided to control the operation of the information processing apparatus and executes an OS, application programs, etc. loaded into the main memory 160 from an external storage unit.

The first high-speed channel circuit 102 is a circuit for communicating with the second high-speed channel circuit 111 of the bridge controller 110. The first initialization circuit 103 is a circuit for executing the initialization (calibration) of the first high-speed channel circuit 102.

The linear temperature sensor 104 is a sensor for monitoring the average temperature of a die at high accuracy (approximately ±1 to 2° C.). The linear temperature sensor 104 is formed of a single analog (diode) cell, and the average temperature of a silicon die of the processor module 100 is read using the temperature controller 130 provided externally.

The bridge controller 110 connected to the processor module 100 includes a video output circuit for outputting video data calculated by the processor module 100 to a display device, audio input/output circuits, digital video input/output interfaces, a network controller, an ATA controller, etc. (these are not shown).

Furthermore, the bridge controller 110 includes the second high-speed channel circuit 111 serving as a second high-speed channel circuit for communicating with the high-speed channel circuit 102 of the processor module 100 and a second initialization circuit 112 for initializing the second high-speed channel circuit 111. Eight-bit parallel communication is performed between the first high-speed channel circuit 102 and the second high-speed channel circuit 111 at a communication speed of 5 Gbps.

The system controller 120 includes an initialization controller 121, a temperature controller control module (temperature ctl control module) 122, a power supply controller control module (power supply ctl control module) 123, and a temperature acquisition module 124. The system controller 120 has a function of monitoring the starting and abnormality for the processor module 100 and the bridge controller 110.

The initialization controller 121 has a function of performing initialization of the entire system. The temperature ctl control module 122 sets and controls with respect to the temperature controller 130. Furthermore, the power supply ctl control module 123 sets and controls with respect to the power supply controller 150. The temperature acquisition module 124 has a function of acquiring temperature read from the linear temperature sensor 104 using the temperature detection circuit 133 of the temperature controller 130.

First, the initialization of the channel circuits 102 and 111 will be described below. A data signal is transmitted from the second high-speed channel circuit 111 to the first high-speed channel circuit 102. The first high-speed channel circuit 102 sweeps sample points for receiving the data signal transmitted from the second high-speed channel circuit 111. When the sample points are swept, there occur two cases: one case wherein the data signal can be received, and the other case wherein the data signal cannot be received. Furthermore, the first high-speed channel circuit 102 is set so that data can be received optimally from the sample points at which the data signal was able to be received. For example, the first high-speed channel circuit 102 is set depending on the center sample point of the sample points at which the data signal was able to be received. After the setting of the first high-speed channel circuit 102 is completed, the setting of the second high-speed channel circuit 111 is performed.

The temperature controller 130 includes a control circuit 131, the temperature detection circuit 133 and a fan control circuit 132. The temperature detection circuit 133, reads the die temperature of the processor module 100 measured using the linear temperature sensor 104. In addition, the fan control circuit 132 controls a rotational speed of the cooling fan 140 for cooling the processor module 100. The control circuit 131 controls the fan control circuit 132 so that the die temperature is maintained in the temperature range specified by the temperature ctl control module 122 depending on the temperature read using the temperature detection circuit 133.

The operation guarantee temperature range of the processor module 100 is ΔT_{—}1=80° C., and the temperature fluctuation range in which the AC characteristics of the I/O section of the first high-speed channel circuit 102 are guaranteed is ΔT_c=55° C. Hence, the temperature fluctuation range of the first high-speed channel circuit 102 is narrower than the operation guarantee temperature range of the processor circuit 101. Because of this difference in the temperature ranges, if the temperature of the processor module 100 becomes higher than the temperature of the first high-speed channel circuit 102 at the time of the initialization thereof, the first high-speed channel circuit 102 cannot perform communication normally.

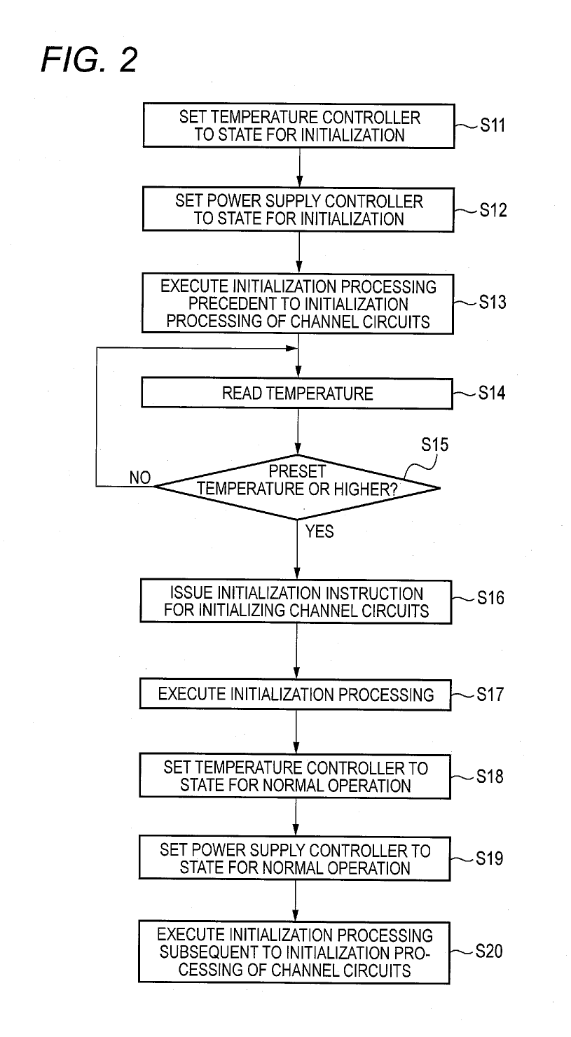

FIG. 2 shows an initialization processing flow for normally performing communication in the first high-speed channel circuit 102 even if the temperature of the processor module 100 rises. In this flow, the system controller 120 controls the initialization controller 121, the temperature ctl control module 122, the power supply ctl control module 123 and the temperature acquisition module 124 in the order described below. This flow is an example in which the initialization processing flow is completed.

First, when the user performs power-on operation, the initialization controller of the system controller 120 starts initialization. The temperature ctl control module 122 first sets the temperature controller 130 to a state for initialization processing (at step S11). By the setting of the temperature controller 130 to the state for initialization processing, the temperature controller 130 sets the cooling fan 140 to a stopping state. Since the cooling fan 140 is not rotated, the processor module 100 is not cooled and the temperature of the processor module 100 can be raised.

Furthermore, the power supply ctl control module 123 sets the power supply controller 150 to a state for initialization processing and enables the output of drive power (at step S12). By the setting of the power supply controller to the state for initialization processing and by the enabling of the output of the drive power, the power supply controller 150 starts to supply the drive power to the processor module 100. At the setting of the state for initialization processing, the voltage value of the drive power may be the maximum voltage value in the operation voltage range of the processor module 100. The self-heating of the processor module 100 becomes maximum by applying the maximum voltage value to the processor module 100.

Next, the initialization controller 121 executes processing up to the processing precedent to the initialization processing of the high-speed channel circuits 102 and 111 (at step S13). The processing up to the processing precedent to the initialization processing means the processing to be executed after the activation of the processor module 100 and the bridge controller 110 themselves, that is, preparation for the initialization (calibration) processing of the high-speed channels, such as the setting of the sweeping range and the stepping width for the calibration.

Furthermore, the temperature acquisition section 124 acquires the temperature of the processor module 100 measured using the linear temperature sensor 104 and read using the temperature controller 130 from the temperature controller 130 (at step S14).

Moreover, the initialization controller 121 determines whether the temperature acquired using the temperature acquisition section 124 has become equal to or higher than a preset temperature (at step S15). It is desirable that the preset temperature should be, for example, the difference between the upper limit of the operation guarantee temperature of the processor module 100 and the temperature fluctuation range in which the AC characteristics of the first high-speed channel circuit 102 are guaranteed. In the case of the embodiment, since the upper limit of the operation guarantee temperature is 85° C. and the temperature fluctuation range in which the AC characteristics are guaranteed is 55° C., the preset temperature is 30° C.

The initialization controller 121 periodically acquires the temperature of the processor module 100 and executes the determination of step S15 until the temperature becomes equal to or higher than the preset temperature. When the temperature has become equal to or higher than the preset temperature (YES at step S15), the initialization controller 121 issues an initialization instruction for executing the initialization processing of the first high-speed channel circuit 102 and the second high-speed channel circuit 111 described above to the processor module 100 and the bridge controller 110, respectively (at step S16).

The first initialization circuit 103 of the processor module 100 and the second initialization circuit 112 of the bridge controller 110 execute the above-mentioned initialization processing (the initialization (calibration) processing of the high-speed channels in the initialization processing of the processor module 100 and the bridge controller 110) (at step S17).

After the initialization is completed, the temperature ctl control module 122 resets the setting of the temperature controller 130 to a state for normal system operation according to the instruction from the initialization controller 121. The cooling fan 140 can be rotated by the resetting, and the temperature controller 130 controls the rotation of the cooling fan 140 so that the temperature of the processor module 100 becomes equal to or lower than the upper limit of its operation temperature.

After the initialization is completed, the power supply ctl control module 123 resets the power supply controller 150 to the state for the normal system operation according to the instruction from the initialization controller 121 (at step S19).

Next, the initialization controller 121 executes the initialization processing subsequent to the initialization processing of the high-speed channel circuits (at step S20). When the initialization processing is completed, an OS and application programs are loaded into the main memory 160 from the external storage unit, and the OS and the application programs are executed by the processor circuit 101.

According to the embodiment, since the initialization processing of the first high-speed channel circuit 102 is executed after the temperature of the processor module 100 has become 30° C., the communication between the processor module 100 and the bridge controller 110 can be performed normally even if the temperature of the processor module 100 has become the upper limit of the operation guarantee temperature. A case in which the initialization processing of the first high-speed channel circuit 102 is executed when the temperature of the processor module 100 is 20° C. is herein taken as an example. In this case, since the temperature fluctuation range in which the AC characteristics of the first high-speed channel circuit 102 are guaranteed is 55° C., the upper limit of the temperature at which the first high-speed channel circuit 102 can perform communication normally is 75° C.

Hence, if the temperature of the processor module 100 has become the upper limit (85° C.) of the operation guarantee temperature, the first high-speed channel circuit 102 cannot perform communication normally. However, when the initialization processing of the first high-speed channel circuit is performed after the temperature of the processor module 100 has become 30° C., the upper limit of the temperature at which the first high-speed channel circuit 102 can perform communication normally becomes 85° C. Hence, the first high-speed channel circuit 102 can perform communication normally even if the temperature of the processor module 100 becomes the upper limit (85° C.) of the operation guarantee temperature.

In the case of the embodiment, since the initialization processing of the first high-speed channel circuit 102 is executed after the temperature of the processor module 100 has become 30° C., the starting time of the system may become long. In the case that the starting time is the first priority, it is desirable that power should be supplied to the processor module 100 at all times. Furthermore, a heater may be mounted on the processor module 100 so that the processor module 100 is heated using the heater. Moreover, the temperature rising may be accelerated by causing the processor circuit 101 to execute a program capable of executing processing only within the processor circuit 101 at the time of the power-on operation by the user.

In the case that power is supplied to the processor module 100 at all times or the processor module 100 is heated using the heater, a disadvantage of increasing the standby power of the system occurs in compensation for the advantage of being capable of shortening the period between the power-on operation by the user and the start of the execution of software. Accordingly, in a system wherein a period in which the high-speed channels cannot be used temporarily is allowed to exist after the execution of the software, for the purpose of shortening the apparent starting time of the system, the processor module 100 is started once while the temperature of the system is maintained at its initial temperature. When the temperature of the silicon of the processor module has exceeded 30° C. after the start of the execution of the software, the initialization processing of the high-speed channels is executed again. As a result, the wait time for the rising of the temperature of the silicon can be suppressed, and the increase in the standby power can be eliminated.

An example in which the setting temperature for the cooling operation performed conventionally is 30° C. is described above. However, it is possible to perform operation so that the temperature fluctuation amount across both ends of a channel is restrained further positively by changing the setting temperature to 5° C. as described below.

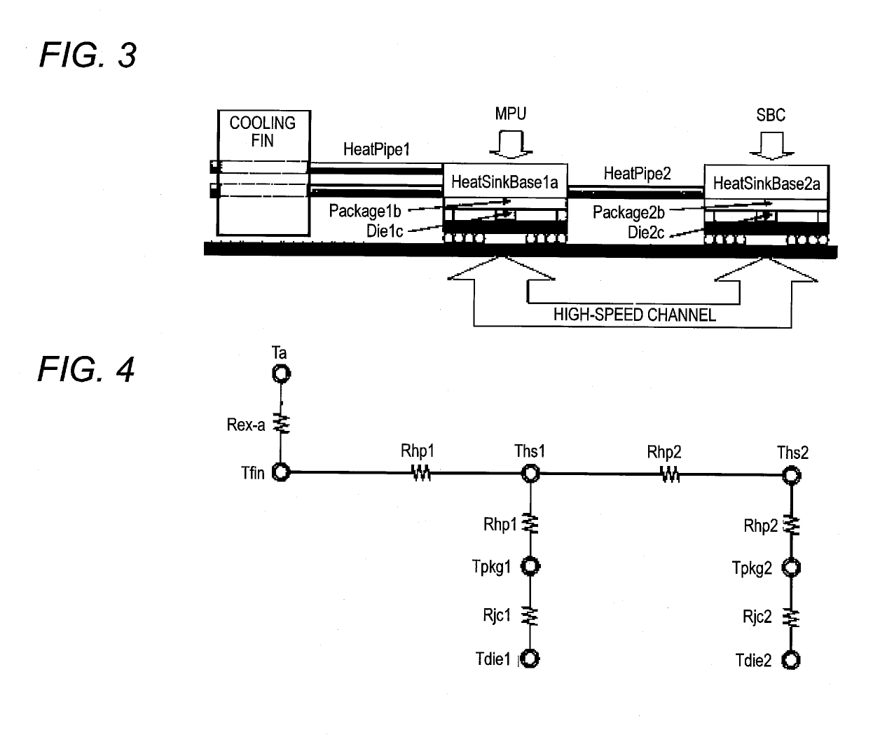

FIG. 3 is a view illustrating a configuration example of the cooling apparatus according to the embodiment.

An MPU (processor module 100) is a first object to be cooled and serves as one end of a high-speed channel. An SBC (bridge controller 110) is a second object to be cooled and serves as the other end of the high-speed channel. In addition, a cooling fin is a fin (for example, a cooling fin equipped with the cooling fan 140) for cooling both the MPU and SBC.

Heat pipes 1 are first heat pipes for thermally coupling the cooling fin to a heat sink base 1a (a heat sink base for the MPU), and the heat sink base 1a is a first heat sink base for cooling a package 1b of the MPU. In addition, the package 1b is a first package serving as the lid (a heat radiating surface) of the MPU, and a die 1c is a first die serving as the silicon of the MPU.

In the case that the MPU is package-less or lid-less, the package 1b does not exist, and the heat sink base 1a directly cools the die 1c.

A heat pipe 2 is a second heat pipe for thermally coupling the heat sink base la to a heat sink base 2a (a heat sink base for the SBC), and the heat sink base 2a is a second heat sink base for cooling a package 2b of the SBC. In addition, the package 2b is a second package serving as the lid (a heat radiating surface) of the SBC, and a die 2c is a second die serving as the silicon of the SBC.

In the case that the SBC is package-less or lid-less, the package 2b does not exist, and the heat sink base 2a directly cools the die 2c.

FIG. 4 is a diagram of a thermal radiation equivalent circuit in which concentrated constants according to the embodiment are used.

The following are available as points to be controlled as the temperatures [deg C] (° C.) at the various sections.

Ta: the operation temperature range of the set (the ambient temperature for the cooling apparatus)
Tfin: the temperature of the cooling fin
Ths1: the temperature of the first heat sink base 1a
Tpkg1: the temperature of the package 1b of the MPU
Tdie1: the temperature of the die 1c of the MPU
Ths2: the temperature of the second heat sink base 2a
Tpkg2: the temperature of the package 2b of the SBC
Tdie2: the temperature of the die 2c of the SBC

Furthermore, the following constituent elements are available as the thermal resistances [deg C/W] of the various sections.

Rex-a: the thermal resistance between the cooling fin and the atmosphere
Rhp1: the thermal resistance of the first heat pipes 1
Rhs1: the thermal resistance of the first heat sink
Rjc1: the thermal resistance between the junction (die) and the case (package) of the MPU

In the case that the MPU is package-less or lid-less, Rjh1 (the thermal resistance between the junction and the heat sink) is used instead of Rjc1.

Rhp2: the thermal resistance of the second heat pipe 2
Rhs2: the thermal resistance of the second heat sink
Rjc2: the thermal resistance between the junction (die) and the case (package) of the SBC

In the case that the SBC is package-less or lid-less, Rjh2 (the thermal resistance between the junction and the heat sink) is used instead of Rjc2.

### (Verification of Operation Temperature)

The operation temperatures for the below-mentioned four examples (1) to (4) will be described below under the following settings.

First, it is assumed that the operation temperature range of the information-processing apparatus set is Ta=5 to 40 [deg C] and that the temperature specifications of the MPU/SBC and the high-speed channel are as described below.

PKG thermal resistance Rjc (inversely proportional to the die area): Rjc of MPU (Rjc1)<Rjc of SBC (Rjc2)

For example, (Rjc1=0.20 [deg C/W])<(Rjc2=0.40 [deg C/W])

Case temperature: the case temperature of MPU (Tpk1)<the case temperature of SBC (Tpk2)

For example, (Tpk1=70 [deg C]<(Tpk2=75 [deg C])

Junction temperature: the junction temperature of MPU (Tjc1)<the junction temperature of SBC (Tjc2)

For example, (Tjc1=80 [deg C])<(Tjc2=85 [deg C])

Operation temperature range of high-speed channel: +55 [deg C]

In the embodiment, the following thermal design and setting values are applied.

Thermal resistance of waste heat from the cooling fin to Ta: Rex-a=0.20 [deg C/W]
Thermal resistance of the first heat pipes 1: Rhp1=0.10 [deg C/W] (two heat pipes are connected between the fin and the MPU)
Thermal resistance of the second heat pipe 2: Rhp2=0.20 [deg C/W] (one heat pipe is connected between the MPU and the SBC)
Thermal resistance of the first heat sink: Rhs1=0.05 [deg C/W] (the same component is used if the MPU and the SBC have equivalent sizes)
Thermal resistance of the second heat sink: Rhs2=0.05 [deg C/W] (the same component is used if the MPU and the SBC have equivalent sizes)
Initialization power: initialization power of MPU (Pmpu)>initialization power of SBC (Psbc)

For example, (Pmpu=30 [W])>(Psbc=15 [W])

Unloaded power: unloaded power of MPU (Pmpu)>unloaded power of SBC (Psbc)

For example, (Pmpu=40 [W])>(Psbc=20 [W])

Maximum power consumption: maximum power consumption of MPU (Pmpu)>maximum power consumption of SBC (Psbc)

For example, (Pmpu=50 [W])>(Psbc=25 [W])

Since the SBC is heated by the heat generation of the MPU at the time of power-on operation, the temperature difference at the silicon (die) at each of both ends of the high-speed channel can be restrained within a desired range (the temperature fluctuation amount at each of both ends can be restrained within 55 [deg C] and the temperature fluctuation amount between both ends can be restrained within ±10 [%] in the embodiment). The following shows the temperature states at the various sections in the operation states (1) to (4) of the set (system).

(1) An example of temperature fluctuation at both ends of the MPU/SBC in the case that the system is started at Ta=5 [deg C]

The following are the temperatures at various sections of the common sections.

Tfin=Ta+(Rex-a×(Pmpu+Psbc))=5+(0.2×(30+15))=14.0[deg C]

Ths1=Tfin+(Rhp1×(Pmpu+Psbc))=14+(0.1×(30+15))=18.5[deg C]

The following are the temperatures at various sections on the side of the MPU.

Tpkg1=Ths1+(Rhs1×Pmpu)=18.5+(0.1×30)=21.5[deg C]

Tdie1−0=Tpkg1+(Rjc1×Pmpu)=21.5+(0.2×30)=27.5[deg C],

wherein the reference (calibration execution) temperature on the side of the MPU is obtained at the minimum temperature of the die of the MPU.

The following are the temperatures at the various sections on the side of the SBC.

Ths2=Ths1+(Rhp2×Psbc)=18.5+(0.2×15)=21.5[deg C]

Tpkg2=Ths2+(Rhs2×Psbc)=21.5+(0.1×15)=23.0[deg C]

Tdie2−0=Tpkg2+(Rjc2×Psbc)=23.0+(0.4×15)=29.0[deg C],

wherein the reference (calibration execution) temperature on the side of the SBC is obtained at the minimum temperature of the die of the SBC.

The following is the temperature difference between the SBC and the MPU.

dT12=Tdie2−0−Tdie1−0=29.0−27.5=1.5[deg C]

(2) An example of temperature fluctuation at both ends of the MPU/SBC in the case that both the MPU and the SBC are under high-load operation at Ta=40 [deg C]

The following are the temperatures at various sections of the common sections.

Tfin=Ta+(Rex-a×(Pmpu+Psbc))=40+(0.2×(50+25))=55.0[deg C]

Ths1=Tfin+(Rhp1×(Pmpu+Psbc))=55+(0.1×(50+25))=62.5[deg C]

The following are the temperatures at various sections on the side of the MPU.

Tpkg1=Ths1+(Rhs1×Pmpu)=62.5+(0.1×50)=67.5[deg C]

Tdie1−1=Tpkg1+(Rjc1×Pmpu)=67.5+(0.2×50)=77.5[deg C],

the maximum temperature of the die of the MPU

dT1−1=Tdie1−1−Tdie1−0=77.5−27.5=50.0[deg C],

whereby the maximum temperature difference on the side of the MPU is restrained within 55 [deg C].

The following are the temperatures at the various sections on the side of the SBC.

Ths2=Ths1+(Rhp2×Psbc)=62.5+(0.2×25)=67.5[deg C]

Tpkg2=Ths2+(Rhs2×Psbc)=67.5+(0.1×25)=70[deg C]

Tdie2−1=Tpag2+(Rjc2×Psbc)=70.0+(0.4×25)=80.0[deg C],

the maximum temperature of the die of the SBC

dT2−1=Tdie2−1−Tdie2−0=80.0−29.0=51.0[deg C],

whereby the maximum temperature difference on the side of the SBC is restrained within 55 [deg C].

The following is the temperature difference between the SBC and the MPU.

dT12=Tdie2−1−Tdie1−1=51.0−50.5=1.0[deg C]

The following is the temperature fluctuation ratio at both ends while the temperature at the starting time is used as the reference.

R_diff=|dT2−1−dT1−1|/Min.(dT1−1,dT2−1)×100=1/50×100=2.0[%],

whereby the temperature difference between the MPU and the SBC is restrained within 10 [%].
(3) An example of temperature fluctuation at both ends of the MPU/SBC in the case that the MPU is under high-load operation and the SBC is under low-load operation at Ta=40 [deg C]

The following are the temperatures at various sections of the common sections.

Tfin=Ta+(Rex-a×(Pmpu+Psbc)=40+(0.2×(50+20))=54.0[deg C]

Ths1=Tfin+(Rhp1×(Pmpu+Psbc)=54+(0.1×(50+20))=61.0[deg C]

The following are the temperatures at various sections on the side of the MPU.

Tpkg1=Ths1+(Rhs1×Pmpu)=61.0+(0.1×50)=66.0[deg C]

Tdie1−2=Tpkg1+(Rjc1×Pmpu)=66.0+(0.2×50)=76.0[deg C],

the maximum temperature of the die of the MPU

dT1−2=Tdie1−2−Tdie1−0=76.0−27.5=48.5[deg C],

whereby the maximum temperature difference on the side of the MPU is restrained within 55 [deg C].

The following are the temperatures at the various sections on the side of the SBC.

Ths2=Ths1+(Rhp2×Psbc)=61.0+(0.2×20)=65.0[deg C]

Tpkg2=Ths2+(Rhs2×Psbc)=65.0+(0.1×20)=67.0[deg C]

Tdie2−2=Tpag2+(Rjc2×Psbc)=67.0+(0.4×20)=75.0[deg C],

the maximum temperature of the die of the SBC

dT2−2=Tdie2−2−Tdie2−0=75.0−29.0=46.0[deg C],

whereby the maximum temperature difference on the side of the SBC is restrained within 55 [deg C].

The following is the temperature difference between the SBC and the MPU.

dT12=Tdie2−2−Tdie1−2=46.0−48.5=−2.5[deg C]

The following is the temperature fluctuation ratio at both ends while the temperature at the starting time is used as the reference.

R_diff=|dT2−2−dT1−2|/Min.(dT1−2,dT2−2)×100=2.5/46×100=5.5[%],

whereby the temperature difference between the MPU and the SBC is restrained within 10 [%].
(4) An example of temperature fluctuation at both ends of the MPU/SBC in the case that the MPU is under low-load operation and the SBC is under high-load operation at Ta=40 [deg C]

The following are the temperatures at various sections of the common sections.

Tfin=Ta+(Rex-a×(Pmpu+Psbc))=40+(0.2×(40+25))=53.0[deg C]

Ths1=Tfin+(Rhp1×(Pmpu+Psbc))=53+(0.1×(40+25))=59.0[deg C]

The following are the temperatures at various sections on the side of the MPU.

Tpkg1=Ths1+(Rhs1×Pmpu)=59.5+(0.1×40)=63.5[deg C]

Tdie1−3=Tpkg1+(Rjc1×Pmpu)=63.5+(0.2×40)=71.5[deg C],

the maximum temperature of the die of the MPU

dT1−3=Tdie1−3−Tdie1−0=71.5−27.5=44.0[deg C],

whereby the maximum temperature difference on the side of the MPU is restrained within 55 [deg C].

The following are the temperatures at the various sections on the side of the SBC.

Ths2=Ths1+(Rhp2×Psbc)=59.5+(0.2×25)=64.5[deg C]

Tpkg2=Ths2+(Rhs2×Psbc)=64.5+(0.1×25)=67.0[deg C]

Tdie2−3=Tpkg2+(Rjc2×Psbc)=67.0+(0.4×25)=77.0[deg C],

the maximum temperature of the die of the SBC

dT2−3=Tdie2−3−Tdie2−0=77.0−29.0=48.0[deg C],

whereby the maximum temperature difference on the side of the SBC is restrained within 55 [deg C].

The following is the temperature difference between the SBC and the MPU.

dT12=Tdie2−3−Tdie1−3=77.0−71.5=5.5[deg C]

The following is the temperature fluctuation ratio at both ends while the temperature at the starting time is used as the reference.

R_diff=|dT2−3−dT1−3|/Min.(dT1−3,dT2−3)×100=3.5/44×100=7.9[%],

whereby the temperature difference between the MPU and the SBC is restrained within 10 [%].

Heat sinks for high-power devices have been usually separated individually to avoid mutual influence. In the embodiment, however, the heat sink bases being separated are coupled to each other using a heat pipe.

In addition, a high-speed channel being point-to-point connected has a characteristic in which its operable range drifts depending on the temperature difference between both ends thereof, and the amount of the drift can be reduced by decreasing the temperature difference between both ends (by changing the temperatures at both ends in the same direction). Hence, the high-speed channel can be maintained in its stable operation range or can support a higher transmission rate by sharing the heat sinks so as to decrease the temperature difference between the devices at both ends of the high-speed channel.

Due to use of the cooling apparatus according to the embodiment, the heat generated at the MPU (micro processing unit) having large power consumption is used to heat the SBC (south bridge chip) having small power consumption, whereby the temperature fluctuation range at the high-speed channel of the SBC is reduced. Furthermore, the temperature fluctuations of the MPU and SBC are guided in the same direction, whereby, for example, eye pattern drifts at the high-speed channels are canceled each other. Hence, it is possible to securely obtain an operation margin relating to the temperature fluctuation in the high-speed channel. As a result, it is possible to ease constraints on the design relating to the crosstalk (in the wiring) and the voltage fluctuation (in the power supply circuit and decoupling-C) adversely affecting the operation margin of the high-speed channel, thereby being possible to reduce cost.

As in the case of the embodiment as shown in FIG. 2, the processor modules are self-heated at the time of power-on operation and the system waits for temperature rise due to use of the heater to reduce the temperature difference across the high-speed channel. Furthermore, in addition to the above-mentioned effect, the embodiment is effective in shifting the temperature fluctuations at both ends of the channel in the same direction (effective in not allowing the temperature fluctuations to become independent).

For the purpose of increasing the operation margin of the high-speed channel by minimizing the temperature fluctuations at both ends and the temperature difference between both ends of the “high-speed channel” point-to-point connected between the MPU and the SBC as described above, the following configuration is adopted under the conditions of Tj1≦Tj2 (Tjc1=80 [deg C] and Tjc2=85 [deg C] in the embodiment) and P1≧P2 (Pmpu max=50 [W] and Psbc max=25 [W] in the embodiment).

In other words, the cooling apparatus is configured so that the heat sinks and the cooling fin are arranged so as to have the above-mentioned positional relationship with respect to thermal resistance. More specifically, the cooling apparatus has a configuration in which two heat pipes are used to thermally couple the cooling fin to the heat sink base on the side of the device (MPU) having high power consumption, and one heat pipe is used to thermally couple the heat sink base on the side of the device (MPU) having high power consumption to the heat sink base on the side of the device (SBC) having low power consumption, whereby the cooling apparatus functions so that the device (SBC) having low power consumption is heated by the device (MPU) having high power consumption at the time of power-on operation and so that the temperature difference between the devices (the MPU and the SBC) is reduced during the operation of system.

However, the present invention is not limited to the above-mentioned embodiment, but can be modified variously within a range not departing from the gist of the invention. For example, it is possible to make a configuration effective in which the heat sink bases of the MPU (CBE) and the SBC (SCC) are connected intentionally to each other.

While certain embodiment has been described, the exemplary embodiment has been presented by way of example only, and is not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A cooling apparatus comprising:
a cooling fin configured to cool heat-generating components by radiating heat of the heat-generating components, a first semiconductor module configured to serve as one of the heat-generating components,
a second semiconductor module configured to serve as another one of the heat-generating components,
a first heat sink configured to cool the first semiconductor module, a second heat sink configured to cool the second semiconductor module,
a first heat pipe configured to thermally couple the cooling fin to the first heat sink, and
a second heat pipe configured to thermally couple the first heat sink to the second heat sink, wherein
a functional upper limit of a junction temperature of the first semiconductor module is lower than a functional upper limit of a junction temperature of the second semiconductor module, and a heat generation of the first semiconductor module is larger than a heat generation of the second semiconductor module.

2. The apparatus of claim 1, wherein the first semiconductor module communicates with the second semiconductor module via a high-speed channel.

3. The apparatus of claim 2, further comprising;
a heat controller configured to reduce a difference between the temperature of said high-speed channel on a side of the first semiconductor module and the temperature of the high-speed channel on a side of the second semiconductor module.
